(19) United States
(12) Patent Application Publication
(10) Pub. No.: US 2015/0370377 A1
(43) Pub. Date: Dec. 24, 2015

(54) TOUCH PANEL AND MANUFACTURING METHOD OF TOUCH PANEL

(71) Applicant: Toppan Printing Co., Ltd., Taito-ku (JP)

(72) Inventor: Takanori OHARA, Taito-ku (JP)

(73) Assignee: Toppan Printing Co., Ltd., Taito-ku (JP)

(21) Appl. No.: 14/836,273

(22) Filed: Aug. 26, 2015

Related U.S. Application Data
(63) Continuation of application No. PCT/JP2014/000976, filed on Feb. 25, 2014.

(30) Foreign Application Priority Data
Feb. 27, 2013 (JP) 2013-036695
Aug. 27, 2013 (JP) 2013-175280
Dec. 10, 2013 (JP) 2013-255356

(51) Int. Cl. G06F 3/044; H05K 3/06; H05K 1/02

(52) U.S. Cl. CPC G06F 3/044; H05K 1/0274; H05K 1/0296; H05K 3/06; H05K 2201/0108

(57) ABSTRACT

A touch panel includes a transparent substrate, a wiring formed on at least one surface of the transparent substrate, a conductive layer formed on the wiring and the transparent substrate, and a protective layer formed on the conductive layer. The wiring transmits a signal from the conductive layer. The conductive layer is transparent and has a pattern formed by patterning a material formed on the wiring.

### CROSS-REFERENCE TO RELATED APPLICATIONS

The present application is a continuation of International Application No. PCT/JP2014/000976, filed Feb. 25, 2014, which is based upon and claims the benefits of priority to Japanese Application No. 2013-036695, filed Feb. 27, 2013, Japanese Application No. 2013-175280, filed Aug. 27, 2013, and Japanese Application No. 2013-255356, filed Dec. 10, 2013. The entire contents of all of the above applications are incorporated herein by reference.

### BACKGROUND OF THE INVENTION

1. Field of the Invention

The present invention relates to a touch panel having a pattern of a transparent conductive layer.

2. Discussion of the Background

Touch panels which are a type of input device have been widely used since they allow users to intuitively understand the operation currently performed or the next operation to be performed. The touch panels include a transparent electrode disposed on a liquid crystal display (LCD) screen. When a user touches a certain position on the LCD screen, the touch is detected by a change in voltage at the transparent electrode.

The touch panels are classified according to their sensing methods into optical types, resistance film types, capacitance types, ultrasonic types, electromagnetic induction types and the like. Particularly, in smartphones or tablet PCs for end users, capacitance type touch panels which allow multi-touch operation have been commonly used. As a configuration example of a display device which uses a capacitance type touch panel, a display device includes a display panel such as an LCD, a shield layer disposed on the observation side of the display panel to block noise emission from the LCD display panel, a touch panel disposed on the observation side of the shield layer, and a cover glass or the like to be touched with a finger, disposed on the front side of the touch panel via an adhesive layer or the like. The capacitance type touch panel has an operation principle in which, when a finger touches the outer surface, the touch panel detects a change in capacitance at the electrode in the touch panel, generates data on the amount of change, a position where the change occurred, a state of finger touch and finger movement, and operates based on the data.

The capacitance type touch panel needs X direction electrodes and Y direction electrodes which are perpendicular to the X direction electrodes, and is configured to detect a change in capacitance when a finger touches the touch panel and detect a coordinate of a position of a finger touch to identify the touch position and touch operation. The X electrode layer and the Y electrode layer are not in contact with each other, and are formed via an insulating film. Generally, the X electrode and the Y electrode are made of a transparent conductive material. Each electrode is formed as an electrode layer by depositing and patterning the conductive material on a base material. The patterning shape of the electrode may be linear, diamond-shape or the like. The X direction pattern and the Y direction pattern have a small overlap area in a front view in a layer forming direction.

### SUMMARY OF THE INVENTION

According to one aspect of the present invention, a touch panel includes a transparent substrate, a wiring formed on at least one surface of the transparent substrate, a conductive layer formed on the wiring and the transparent substrate, and a protective layer formed on the conductive layer. The wiring transmits a signal from the conductive layer. The conductive layer is transparent and has a pattern formed by patterning a material formed on the wiring.

According to another aspect of the present invention, a touch panel includes a transparent substrate, a conductive layer formed on at least one surface of the transparent substrate, a wiring which is formed on the conductive layer and transmits a signal from the conductive layer, and a protective layer formed on the wiring and the conductive layer. The conductive layer is transparent and has a pattern formed after the wiring is formed.

According to a still another aspect of the present invention, a method of manufacturing a touch panel includes forming a wiring on at least one surface of a transparent substrate, forming a conductive layer on the wiring and the transparent substrate, and forming a protective layer on the conductive layer. The conductive layer is transparent, the wiring is formed such that the wiring transmits a signal from the conductive layer, and the forming of the conductive layer includes etching the conductive layer before or after the forming of the protective layer on the conductive layer.

According to a still another aspect of the present invention, a method of manufacturing a touch panel includes forming a conductive layer on at least one surface of the transparent substrate, forming a wiring on the conductive layer such that the wiring transmits a signal from the conductive layer, and forming a protective layer on the wiring and the conductive layer. The conductive layer is transparent, and the forming of the conductive layer includes etching of the conductive layer before or after the forming of the protective layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross sectional view which shows a configuration of a display device provided with a touch panel according to an embodiment.

FIG. 2 shows a pattern of a transparent conductive layer of the touch panel according to the embodiment.

FIG. 3 shows a pattern of a transparent conductive layer of the touch panel according to the embodiment.

FIG. 4 is a cross sectional view which shows a configuration of the touch panel according to the embodiment.

FIG. 5 is a cross sectional view which shows a configuration of the touch panel according to the embodiment.

FIG. 6 is a cross sectional view which shows a configuration of the touch panel according to the embodiment.

FIG. 7 is a cross sectional view which shows a configuration of the touch panel according to the embodiment.

FIG. 8 is a schematic view which shows a manufacturing process of the touch panel according to the embodiment.

FIG. 9 is a schematic view which shows a manufacturing process of the touch panel according to the embodiment.

FIG. 10 is a schematic view which shows a manufacturing process of the touch panel according to the embodiment.

FIG. 11 is a schematic view which shows a manufacturing process of the touch panel according to the embodiment.

FIG. 12 is a schematic view which shows a manufacturing process of the touch panel according to the embodiment.

FIG. 13 is a cross sectional view which shows a configuration of the touch panel according to the embodiment.

FIG. 14 is a cross sectional view which shows a configuration of the touch panel according to the embodiment.

### DESCRIPTION OF THE EMBODIMENTS

The embodiments will now be described with reference to the accompanying drawings, wherein like reference numerals designate corresponding or identical elements throughout the various drawings.

An embodiment of the present invention will be described in detail.

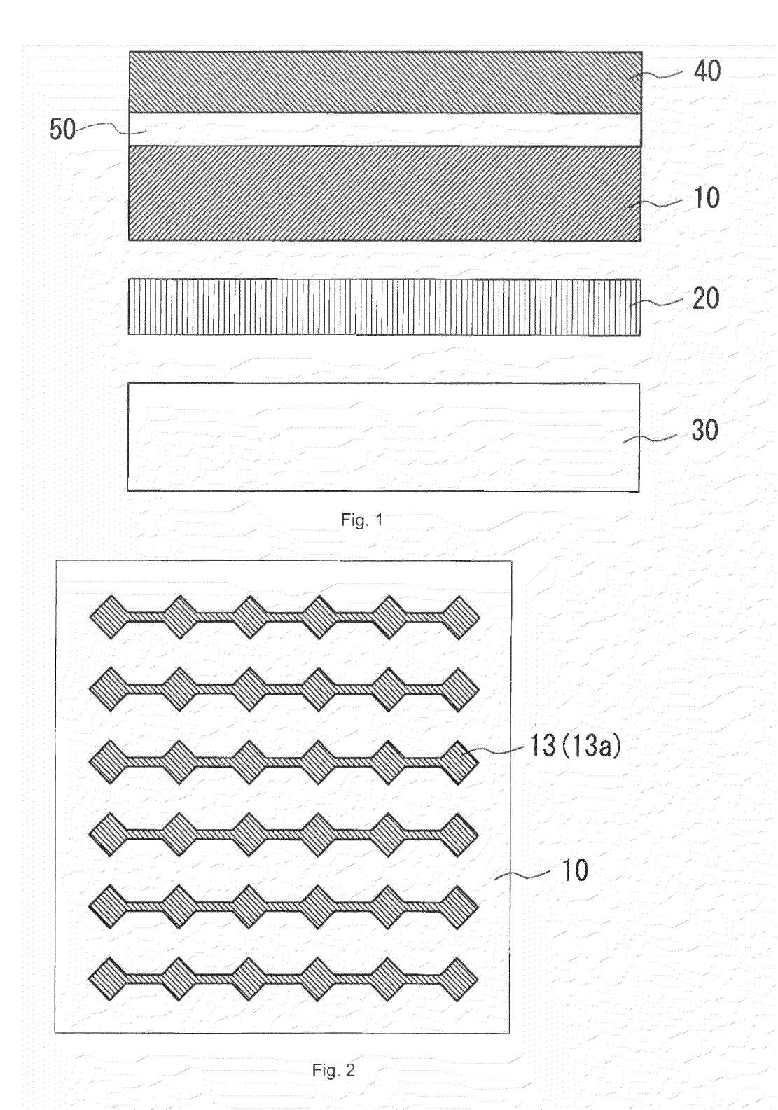

FIG. 1 is a cross sectional view which shows a configuration of a display device provided with a touch panel. The display device shown in FIG. 1 includes an LCD display panel 30, a touch panel 10 disposed on an observation side (front side) of the LCD display panel 30, a front panel layer 40 formed on an observation side (front side) surface of the touch panel 10 via an adhesive layer 50, and a shield layer 20 interposed between the LCD display panel 30 and the touch panel 10. The shield layer 20 may be separated from the touch panel 10 as shown in FIG. 1, or may be bonded to the touch panel 10 via an adhesive or the like. Alternatively, the shield layer 20 may be included in the touch panel 10.

FIG. 2 is an enlarged view of the touch panel 10 of FIG. 1 as seen from one side.

In this embodiment, the touch panel 10 is formed by using a plastic film (transparent substrate) on which a transparent conductive layer 13 (conductive layer) is formed on one or both surfaces thereof. The plastic film is not specifically limited as long as it has sufficient strength during a film deposition process and a post treatment process, and sufficient surface smoothness, and may be formed of, for example, polyethylene terephthalate film, polybutylene terephthalate film, polyethylene naphthalate film, polycarbonate film, polyether sulfone film, polysulfone film, polyacrylate film, and polyimide film. The substrate may contain an additive such as antioxidant, antistatic agent, anti-UV agent, plasticizer, lubricant and easy adhesion agent. Further, in order to improve adhesiveness, a corona treatment or a low temperature plasma treatment may be performed.

Although not shown in the figure, the plastic film may include a UV resin layer. The UV resin layer is used for abrasion resistance or optical adjustment of the plastic film. The UV resin layer may be made of any material as long as it is transparent and has an appropriate hardness and strength. Preferably, a material having the same or approximately same refractive index as that of the plastic film is selected. Further, the resin layer may be made of not only UV-curable resin but also thermosetting resin.

Although not shown in the figure, the plastic film may include an optical function layer. The optical function layer is provided for adjusting the refractive index or the like by varying properties of the transparent conductive material, thereby improving b* value, transmission ratio or the like.

Inorganic compounds used for the optical function layer may include an oxide, sulfide, fluoride, nitride and the like. Specifically, magnesium oxide, silicon dioxide, magnesium fluoride, aluminum fluoride, titanium oxide, zirconium oxide, zinc sulfide, zinc oxide, indium oxide, niobium oxide, tantalum oxide or the like may be used. Since those inorganic compounds have various refractive indexes depending on the material and the film thickness, optical properties can be adjusted by forming the layer by using a material suitable for the purpose and in a specific film thickness. The optical function layer may not be necessarily one layer, and a plurality of layers may be provided, or alternatively, the optical function layer may not be provided.

Materials of the transparent conductive layer 13 (transparent conductive material) may be any of indium oxide, zinc oxide, tin oxide, a mixture of these oxides, a mixture with any other additive, or nano-materials such as carbon nanotube or silver nanowire, and may be selected depending on a required sheet resistance value or optical property, and are not specifically limited.

Methods for forming the transparent conductive layer 13 on the plastic film may include a coating method such as a spin coating method, roller coating method, bar coating method, dip coating method, gravure coating method, curtain coating method, die coating method, spray coating method, doctor coating method, kneader coating method, a print coating method such as a screen printing method, spray printing method, ink jet printing method, relief printing method, intaglio printing method or planographic printing method, and a vacuum deposition method such as a sputtering method. Alternatively, different methods may be selected depending on the transparent conductive member used.

The LCD display panel 30 may be a typical LCD display panel that has a configuration in which a substrate (array substrate) having switching elements that drive a liquid crystal and an electrode layer disposed thereon and a color filter substrate having an opposing electrode layer formed thereon are disposed on opposite sides of the liquid crystal layer, and polarizers are each mounted on the array substrate and the color filter substrate. Driving methods of the LCD display panel 30 include, but are not specifically limited to, the IPS method, TN method, VA method and the like.

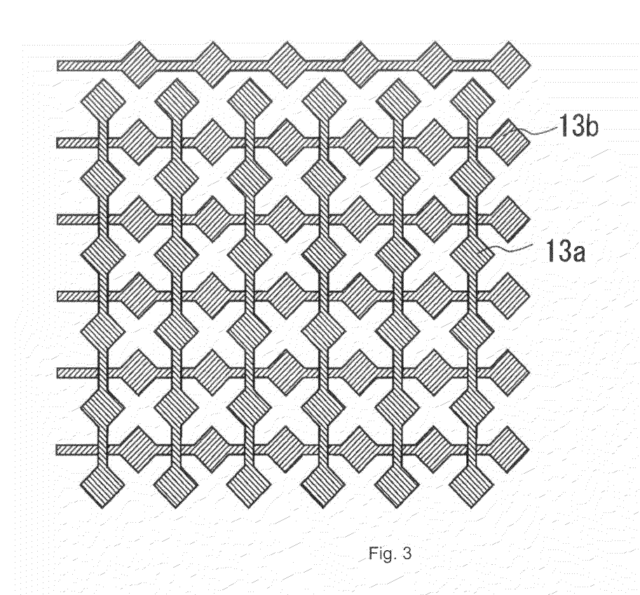

The touch panel 10 has a transparent conductive layer 13a which is patterned in diamond shapes on one surface, and a transparent conductive layer 13b which is also patterned in diamond shapes on the other surface. The diamond shapes of the transparent conductive layer 13a on one surface are disposed not to overlap the diamond shapes of the transparent conductive layer 13b on the other surface. Such arrangement of the touch panel is shown in an enlarged view in FIG. 3. The patterning (patterning for forming a diamond shaped pattern) of the transparent conductive layer 13 forms a conductive pattern section and a non-conductive pattern section by processes of, for example, resist coating, exposure, etching and resist stripping. Patterning methods may include photolithography, screen printing, laser patterning and the like. Further, the resist may not be photosensitive and may be dry-cured. In that case, an exposure process is replaced with a drying process.

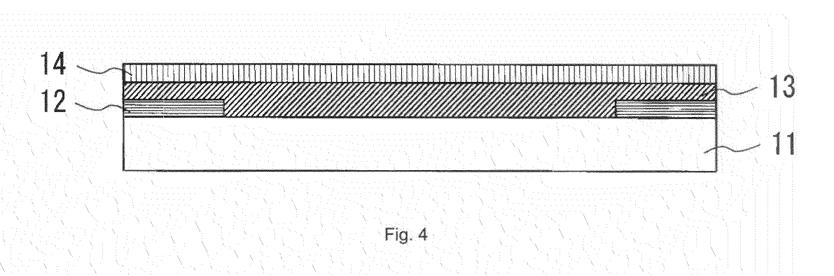

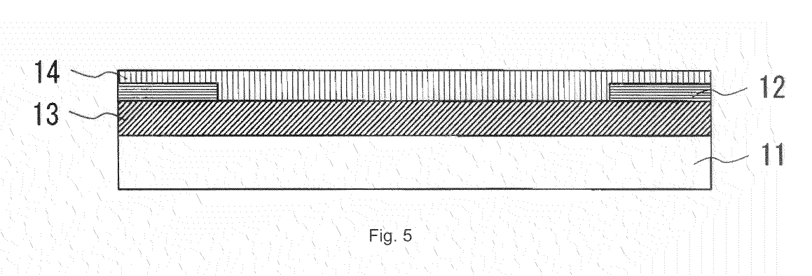

FIG. 4 shows a configuration view of the touch panel 10 according to the present embodiment. In FIG. 4, a wiring 12 for transmitting a signal from the transparent conductive layer 13 is formed on the transparent substrate 11, the transparent conductive layer 13 (conductive layer) is formed on the wiring 12, and a protective layer 14 is formed on the transparent conductive layer 13. Forming methods of the wiring 12 may include screen printing, gravure offset printing, and photolithography patterning. The gravure offset printing is advantageously used to decrease the film thickness of the wiring 12. After the wiring 12 is formed, the transparent conductive layer 13 is formed and the transparent conductive layer 13 is patterned. The patterning method may be any of the above methods. A user can select the most suitable method, and in particular, the photolithography method is advantageously used for precise patterning. Since the wiring 12 is first printed and the transparent conductive layer 13 is then formed on the wiring 12, it is possible to prevent misalignment between the transparent electrode pattern and the wiring due to substrate contraction, which may occur in the conventional method in which the wiring is formed after the patterning of the transparent electrode. Further, the protective layer 14 is formed on the transparent conductive layer 13 to protect the transparent conductive layer 13. The protective layer 14 is formed after the patterning of the transparent conductive layer 13. In some combination of materials of the protective layer 14 and the transparent conductive layer 13, the transparent conductive layer 13 may be etched after the protective layer 14 is formed on the transparent conductive layer 13. In this embodiment, however, regardless of materials of the conductive layer 13 and the protective layer 14, it is possible to perform etching in a short period of time and eliminate etching residue since the protective layer 14 is formed after patterning the transparent conductive layer 13.

Specifically, the protective layer 14 is preferably made of a photo-curable resin such as a monomer or cross-linking oligomer having a main component of tri- or polyfunctional acrylate which is expected to be cross-linked in three dimensional arrays.

The tri- or polyfunctional acrylate monomer is preferably a trimethylolpropane triacrylate, EO-modified isocyanurate triacrylate, pentaerythritol triacrylate, dipentaerythritol triacrylate, dipentaerythritol tetraacrylate, dipentaerythritol pentaacrylate, dipentaerythritol hexaacrylate, ditrimethylolpropane tetraacrylate, pentaerythritol tetraacrylate, and polyester acrylate. Particularly, EO-modified isocyanurate triacrylate and polyester acrylate are preferable. They may be used alone or in combination of two or more thereof. Further, a so-called acryl-based resin such as epoxyacrylate, urethaneacrylate and polyolacrylate may also be used in addition to tri- or polyfunctional acrylate.

The cross-linking oligomer is preferably an acryl oligomer such as polyester (meta)acrylate, polyether (meta)acrylate, polyurethane (meta)acrylate, epoxy (meta)acrylate and silicone (meta)acrylate. Specifically, polyethylene glycol di(meta)acrylate, polypropylene glycol di(meta)acrylate, bisphenol A epoxy acrylate, diacrylate of polyurethane, and cresol novolac epoxy (meta)acrylate may be used.

The protective layer 14 may include an additive such as a photopolymerization initiator. When the photopolymerization initiator is added, radical generating photopolymerization initiators may be benzoins and alkyl ethers thereof such as benzoin, benzoin methyl ether, benzoin ethyl ether, benzoin isopropyl ether, benzyl methyl ketal, acetophenones such as acetophenone, 2,2-dimethoxy-2-phenyl acetophenone, 1-hydroxycyclohexyl phenyl ketone, anthraquinones such as methyl anthraquinone, 2-ethyl anthraquinone, 2-amylanthraquinone, thioxanthones such as thioxanthone, 2,4-diethylthioxanthone, 2,4-diisopropyl thioxanthone, ketals such as acetophenone dimethylketal, benzyl dimethyl ketal, benzophenones such as benzophenone, 4,4-bismethyl aminobenzophenone and azo compounds. They can be used alone or as a mixture of two or more thereof, or even in combination with a photoinitiation auxiliary such as tertiary amines such as triethanolamine, methyldiethanol amine, benzoic acid derivatives such as 2-dimethylaminoethyl benzoate, 4-dimethylamino benzoic acid ethyl ester.

The addition amount of the above photopolymerization initiator is in the range of 0.1% by weight or more and 10% by weight or less and more preferably, 0.5% by weight or more and 5% by weight or less of the main component resin. If the amount is less than the lower limit, a cured film layer is not sufficiently cured, which is not desirable. Further, if the amount is over the upper limit, the cured film layer has a yellow discoloration or decrease in weather resistance, which is not desirable. Light used for curing a photo-curable resin is ultraviolet light, electron beams, gamma rays or the like. In a case of electron beams or gamma rays, a photopolymerization initiator or a photoinitiation auxiliary may not necessarily be added. The radiation source may be a high pressure mercury lamp, xenon lamp, metal halide lamp, accelerated electron generator or the like.

FIG. 5 shows another configuration view of the touch panel 10 according to the present embodiment. Unlike the example shown in FIG. 4, the transparent conductive layer 13 is formed on the transparent substrate 11, and the wiring 12 is formed on the transparent conductive layer 13. After the wiring 12 is formed, the transparent conductive layer 13 is patterned. Since the transparent conductive layer 13 is patterned after forming the wiring 12, misalignment between the transparent electrode and the wiring 12 does not occur. Further, since the protective layer 14 is provided after patterning the conductive layer 13, etching residue in an etched portion can be eliminated. The patterning method and forming method of the wiring 12 may be the same as those described in FIG. 4.

In examples shown in FIGS. 4, 5 and 14, which will be described later, the transparent substrate 11 preferably has a thickness of 25 μm to 250 μm. The wiring 12 preferably has a thickness of 3 μm to 10 μm. Further, a width of the wiring 12 and an interval between the wirings 12 are preferably 5 μm to 100 μm. More preferably, the transparent substrate 11 has a thickness of 25 μm to 50 μm. The wiring 12 has a thickness of 3 μm to 5 μm. A width of the wiring 12 and an interval of the wiring 12 are 15 μm to 20 μm.

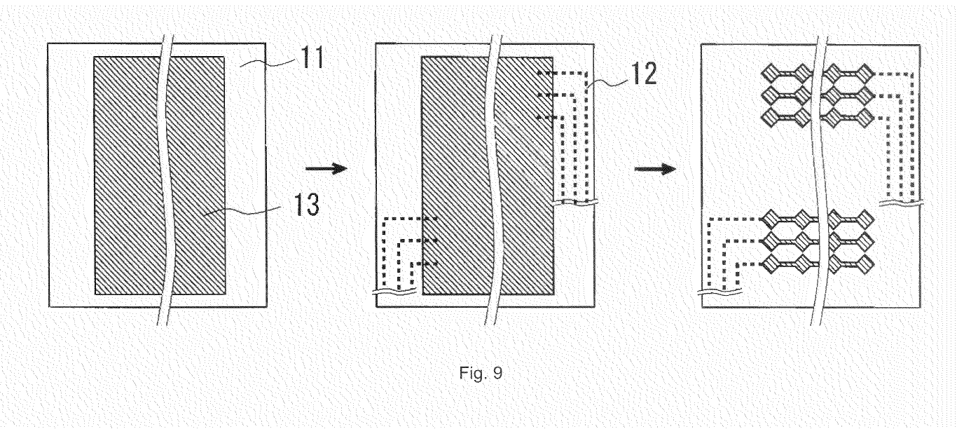

FIG. 8 is a view of the touch panel 10 of FIG. 4 as seen from just above the transparent substrate 11 which shows how the wiring 12 and the transparent conductive layer 13 are formed (the protective layer 14 is not shown in the figure). FIG. 9 is a view of the touch panel 10 of FIG. 5 as seen from just above the transparent substrate 11 which shows how the wiring 12 and the transparent conductive layer 13 are formed (protective layer 14 is not shown in the figure). Instead of forming the wiring 12 on the patterned transparent conductive layer 13, the transparent conductive layer 13 is (solidly) formed on a flat film and the pre-patterned wiring 12 is formed thereon.

Specifically, a manufacturing method of the touch panel of FIG. 8 includes a wiring forming process for forming the wiring 12 on the transparent substrate 11, a conductive layer forming process for forming the transparent conductive layer 13 after the wiring forming process, and a pattern forming process for patterning the transparent conductive layer 13. In FIG. 8, the transparent conductive layer 13 is solidly formed after the patterned wiring 12 is formed. The pattern forming process is performed, for example, after a protective layer forming process for pattern printing the pattern of the protective layer 14.

A manufacturing method of touch panel of FIG. 9 includes the conductive layer forming process for forming the transparent conductive layer 13 on the transparent substrate 11, the wiring forming process for forming the wiring 12 after the conductive layer forming process, and the pattern forming process for patterning the transparent conductive layer 13. In FIG. 9, the patterned wiring 12 is formed after the transparent conductive layer 13 is solidly formed. The pattern forming process is performed, for example, after the protective layer forming process for pattern printing the pattern of the protective layer 14.

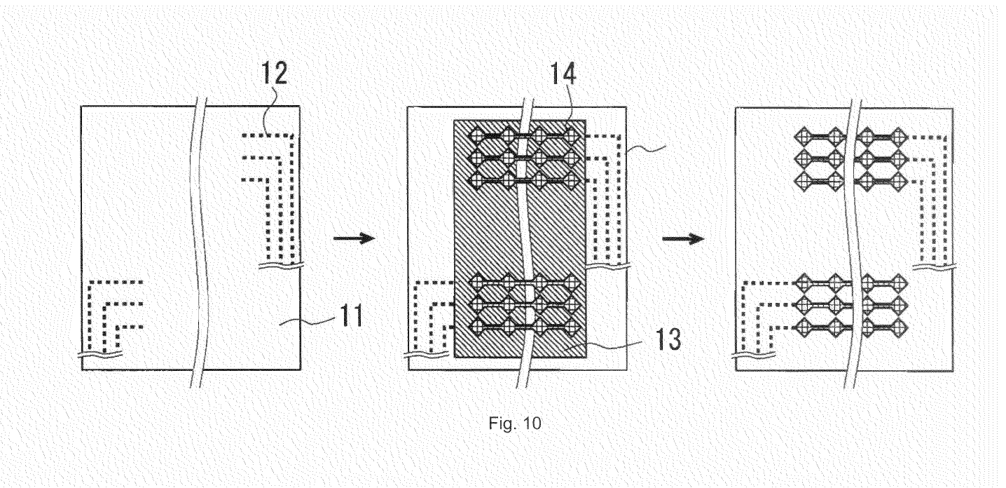

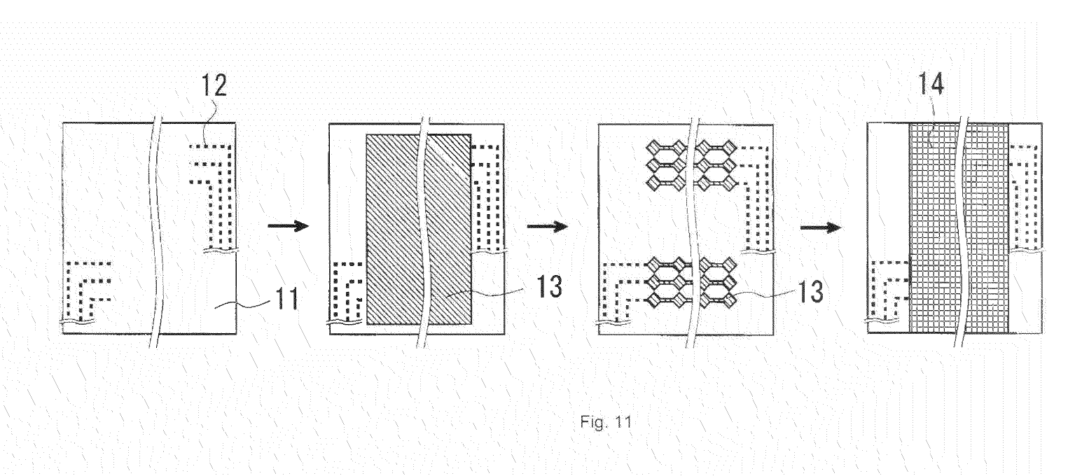

The protective layer 14 may be used as a resist for the patterning of the transparent conductive layer 13 depending on the material. For example, when the transparent conductive layer 13 is patterned by wet etching, a UV resin layer which is not eroded by the etchant may be used as a material of the protective layer 14 and the protective layer 14 may be deposited in a desired etching pattern shape on the transparent conductive layer 13. Then, a desired pattern of the transparent conductive layer 13 can be obtained only by etching the transparent conductive layer 13. This may be performed after the wiring 12 and the transparent conductive layer 13 are formed on the transparent substrate 11 in this order as shown in FIG. 10, or alternatively, may be performed after the transparent conductive layer 13 and the wiring 12 are formed on the transparent substrate 11 in this order. This can eliminate the conductive film residue in a patterning process. Further, another protective layer 14 may be uniformly deposited on the patterned protective layer 14 as necessary.

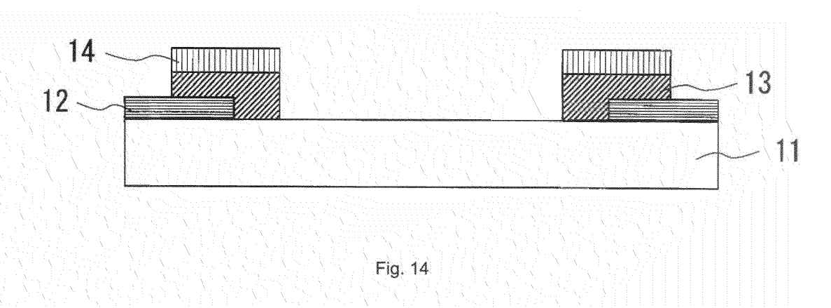

FIG. 14 shows a configuration view of the touch panel 10 according to the present embodiment manufactured by the manufacturing method of the touch panel of FIG. 10. In an example shown in FIG. 14, the wiring 12 that transmits a signal from the transparent conductive layer 13 is formed on the transparent substrate 11, the patterned transparent conductive layer 13 is formed on the wiring 12, and the patterned protective layer 14 is formed on the transparent conductive layer 13. That is, a pattern of the transparent conductive layer 13 is formed by patterning which is performed in a state that the transparent conductive layer 13 is covered by a pattern of the protective layer 14. Alternatively, unlike the example shown in FIG. 14, the patterned transparent conductive layer 13 may be formed on the transparent substrate 11, and then the wiring 12 may be formed on the transparent conductive layer 13. Furthermore, although the patterned protective layer 14 is disposed only on the surface of the patterned transparent conductive layer 13, the protective layer 14 may also be formed on the surface of the wiring 12, not only on the surface of the patterned transparent conductive layer 13.

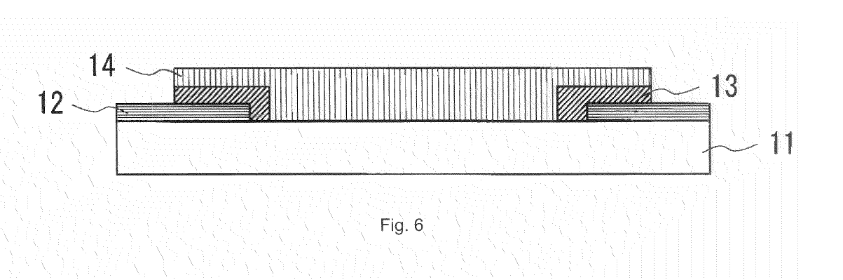

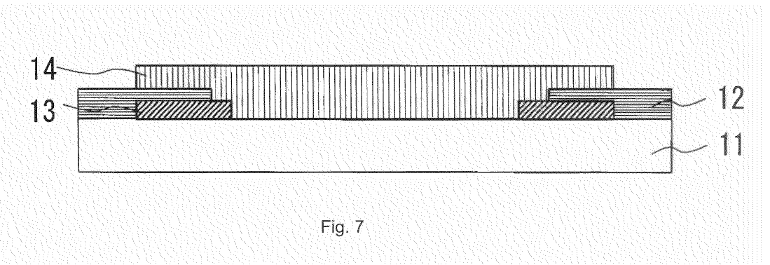

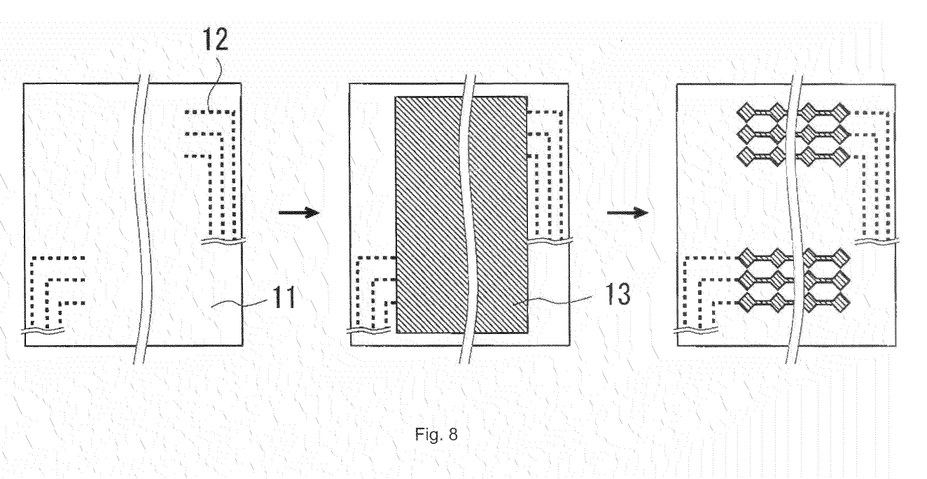

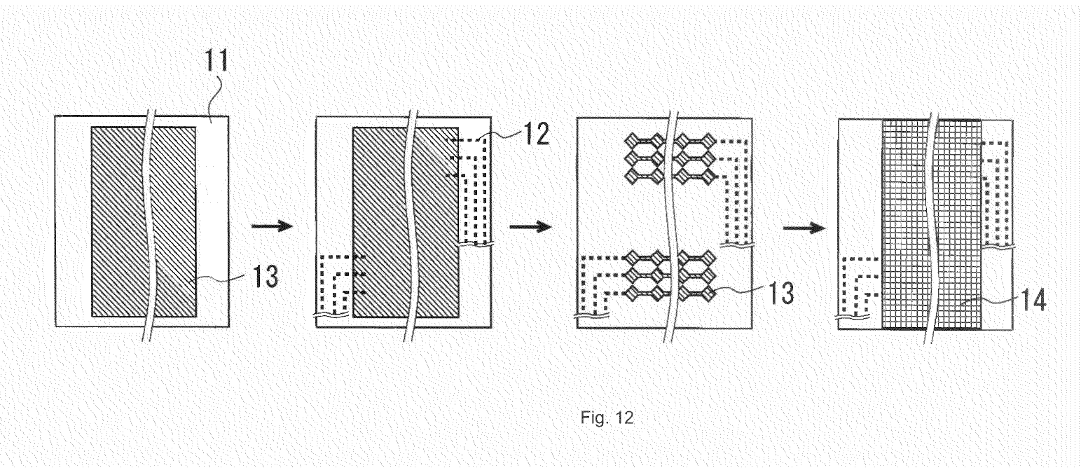

FIGS. 11 and 12 are views which show how the wiring 12, the transparent conductive layer 13 and the protective layer 14 are formed as seen from just above FIGS. 6 and 7. Instead of forming the wiring 12 on the patterned transparent conductive layer 13, the transparent conductive layer 13 is solidly formed and the pre-patterned wiring 12 is formed thereon.

Specifically, a manufacturing method of touch panel of FIG. 11 includes a wiring forming process for forming the wiring 12 on the transparent substrate 11, a conductive layer forming process for forming the transparent conductive layer 13 after the wiring forming process, and a pattern forming process for patterning the transparent conductive layer 13. In FIG. 11, the transparent conductive layer 13 is solidly formed after the patterned wiring 12 is formed. After that, a pattern forming process of the transparent conductive layer 13 is performed, and a forming process of the protective layer 14 is then performed. The protective layer 14 may cover the entire transparent conductive layer 13.

A manufacturing method of touch panel of FIG. 12 includes the conductive layer forming process for forming the transparent conductive layer 13 on the transparent substrate 11, the wiring forming process for forming the wiring 12 after the conductive layer forming process, and the pattern forming process for patterning the transparent conductive layer 13. In FIG. 12, the patterned wiring 12 is formed after the transparent conductive layer 13 is solidly formed. After that, the pattern forming process of the transparent conductive layer 13 is performed, and the forming process of the protective layer 14 is then performed. The protective layer 14 may cover the entire transparent conductive layer 13.

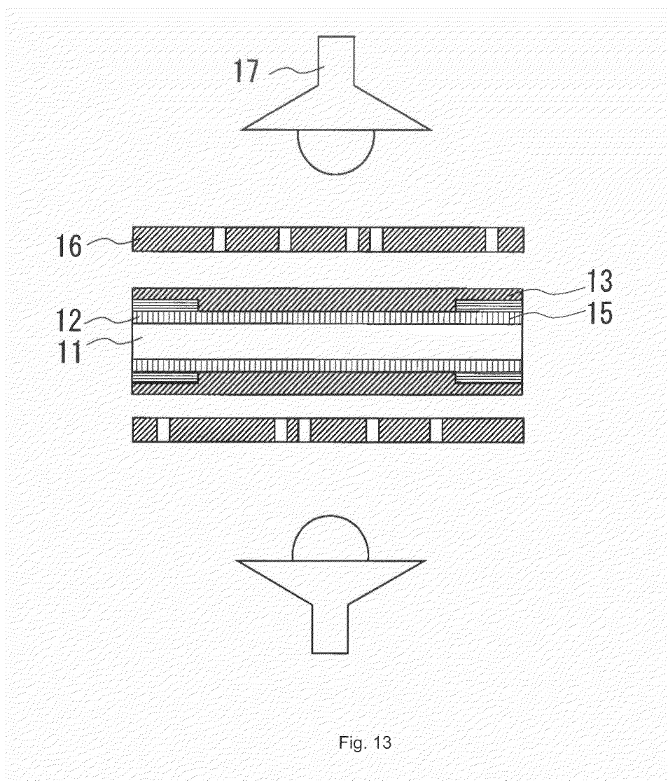

A UV absorbing layer 15 that has a transmittance of less than 1% for light of 365 nm wavelength is preferably disposed on the transparent substrate 11. FIG. 13 is a view which shows the UV absorbing layer 15 is further provided on the transparent substrate 11. FIG. 13 shows the touch panel which includes the transparent substrate 11 on which the UV absorbing layer 15 is formed and cured. In FIG. 13, the UV absorbing layer 15 is directly formed on the transparent substrate 11, and the wiring 12 and the transparent conductive layer 13 are formed on the UV absorbing layer 15. When the transparent conductive layer 13 formed on the transparent substrate 11 is patterned, a photolithography method is advantageously used. The light emitted from the UV light source 17 is shielded by a photomask 16, and cures a photoresist layer (not shown in the figure) disposed on the transparent conductive layer 13 while partially transmitting through it. Since the UV absorbing layer 15 is provided, light emitted from the UV light source 17 does not penetrate the transparent substrate 11 to the back surface and does not interfere with the photoresist on the back surface. The same applies to light emitted from the back surface. That is, the patterns necessary for the touch panel can be formed on both surfaces of the transparent substrate 11 simultaneously by providing separate photomasks on each of the front and back surfaces of the transparent substrate 11. Accordingly, processing steps can be reduced and damage to the transparent substrate 11 can be reduced. The UV absorbing layer 15 can be provided either or both of the surfaces of the transparent substrate 11. Further, the UV absorbing layer 15 may be formed by mixing a UV absorbent in the above UV resin layer. The UV absorbent may be, for example, ULS-935LH manufactured by Ipposha Oil Industries Co., Ltd.

Examples of the present invention will be described. It should be noted that the technical scope of the present invention is not limited to these examples. The characteristics of these examples can be combined or omitted as appropriate to implement the present invention.

### Example 1

A roll of PET substrate (hereinafter, referred to as “substrate”) having a thickness of 50 μm was provided as a transparent substrate. A UV curable resin was applied on both surfaces of the substrate by a die coater and cured to form a resin layer. A UV absorbing resin was mixed in the resin layer so that a transmittance of 365 nm wavelength light becomes 0.7%. Then, a silver wiring of 3 μm thickness was printed on both surfaces of the substrate by gravure offset printing. Then, coating liquid containing dispersed silver nanowires (coating liquid for transparent conductive layer) was applied on the silver wiring by a die coater and cured. Further, a negative dry film resist was provided on both surfaces of the substrate by a roll laminator, exposed to light through a photomask, cured and developed. After development, etching is performed by using copper (II) chloride aqueous solution, and the resist was stripped using an aqueous sodium hydroxide solution to form a diamond-pattern on both surfaces of the substrate as shown in FIG. 2. Then, a protective layer for protecting the transparent conductive layer was formed by a screen printing. Thus, the pattern for the touch panel was formed. The film was cut, and then FPC terminals were provided for the wiring of the touch panel. Normal operation of the touch panel was confirmed.

### Example 2

A roll of PET substrate (hereinafter, referred to as “substrate”) having a thickness of 50 μm was provided as a transparent substrate. A UV curable resin was applied on both surfaces of the substrate by a die coater and cured to form a resin layer. Then, a silver wiring of 3 μm thickness was printed on one surface of the substrate by gravure offset printing. Then, coating liquid containing dispersed silver nanowires (coating liquid for transparent conductive layer) was applied on the silver wiring by a die coater and cured. Further, a negative dry film resist was provided on one surface of the substrate by a roll laminator, exposed to light through a photomask, cured and developed. After development, the resist was etched by using copper (II) chloride aqueous solution and stripped using aqueous sodium hydroxide solution to form a diamond-pattern as shown in FIG. 2. Then, a protective layer for protecting the transparent conductive layer was formed by a screen printing. Another diamond-pattern was formed on the other side of the substrate by the same procedure as described above. The film was cut and bonded to each other, and then FPC terminals were provided for the wiring of the touch panel. Normal operation of the touch panel was confirmed.

### Example 3

A roll of PET substrate having a thickness of 50 μm was provided, and a UV curable resin was applied on both surfaces of the substrate by a die coater and cured. A UV absorbing resin was mixed in the resin layer so that a transmittance of 365 nm wavelength light becomes 0.7%. Then, a silver wiring of 3 μm thickness was printed on both surfaces of the substrate by gravure offset printing. Then, coating liquid containing dispersed silver nanowires was applied on the silver wiring by a die coater and cured to form a transparent conductive layer. Then, a protective layer for protecting the transparent conductive layer was formed on the transparent conductive layer as a resist in a pattern shape by screen printing. The transparent conductive layer was etched by using copper (II) chloride aqueous solution to form a diamond-pattern (the pattern shaped as shown in FIG. 2) which has the protective layer formed on the transparent conductive layer on both surfaces of the substrate as a touch panel pattern. The film was cut, and then FPC terminals were provided for the wiring of the touch panel. Normal operation of the touch panel was confirmed.

### Example 4

A roll of PET substrate having a thickness of 50 μm was provided, and a UV curable resin was applied on both surfaces of the substrate by a die coater and cured. Then, a silver wiring of 3 μm thickness was printed on one surface of the substrate by gravure offset printing. Then, coating liquid containing dispersed silver nanowires was applied on the silver wiring by a die coater and cured to form a transparent conductive layer. Then, a protective layer for protecting the transparent conductive layer was formed on the transparent conductive layer as a resist in a pattern shape by screen printing. The transparent conductive layer was etched by using copper (II) chloride aqueous solution to form a diamond-pattern (the pattern shaped as shown in FIG. 2) which has the protective layer formed on the transparent conductive layer as a touch panel pattern. Another diamond-pattern was formed on the other side of the substrate by the same procedure as described above. The films were cut and bonded to each other, and then FPC terminals were provided for the wiring of the touch panel. Normal operation of the touch panel was confirmed.

### Example 5

A roll of PET substrate having a thickness of 50 μm was provided, and a UV curable resin was applied on both surfaces of the substrate by a die coater and cured. A UV absorbing resin was mixed in the resin layer so that a transmittance of 365 nm wavelength light becomes 0.7%. Then, a silver wiring of 3 μm thickness was printed on both surfaces of the substrate by gravure offset printing. Then, coating liquid containing dispersed silver nanowires was applied on the silver wiring by a die coater and cured to form a transparent conductive layer. A dry film resist (DFR) is provided on the transparent conductive layer on both surfaces of the substrate by a roll laminator. Both surfaces are simultaneously exposed to light through two photomasks, each having a diamond pattern for a capacitive type touch panel (the pattern shaped as shown in FIG. 2). The dry film resist was cured into the touch panel pattern shape, and developed by using an aqueous sodium hydroxide solution as a developer to form a resist pattern in the touch panel pattern shape. Then, the transparent conductive layer was etched by using copper (II) chloride aqueous solution to strip the resist. The transparent conductive layer was formed in the touch panel pattern. After that, a protective layer was formed by solid printing on the entire surface of the touch panel pattern by a screen printing, and dried. The film was cut, and then FPC terminals were provided for the wiring of the touch panel. Normal operation of the touch panel was confirmed.

### Example 6

A roll of PET substrate having a thickness of 50 μm was provided, and a UV curable resin was applied on both surfaces of the substrate by a die coater and cured. The roll substrate was divided, and a silver wiring of 3 μm thickness was printed on one surface of one of the rolls by gravure offset printing. Then, coating liquid containing dispersed silver nanowires was applied on the silver wiring by a die coater and cured to form a transparent conductive layer. After a dry film resist (DFR) is provided on the transparent conductive layer by a roll laminator, exposure is performed by using a photomask having a diamond-pattern for capacitive type touch panel (the X pattern of the shape shown in FIG. 2). The dry film resist was cured into the touch panel pattern shape, and developed by using an aqueous sodium hydroxide solution as a developer to form a resist pattern in the touch panel pattern shape. Then, the transparent conductive layer was etched by using copper (II) chloride aqueous solution to strip the resist. The transparent conductive layer was formed in the X pattern of the diamond of the touch panel. After that, a protective layer was formed by solid printing on the entire surface of the X pattern by screen printing, and dried. Another silver wiring and the transparent conductive layer were formed on one surface of the other roll by the same procedure as described above, and the transparent conductive layer was formed in the Y pattern of the diamond. After that, a protective layer was formed by screen printing. The films were cut and bonded to each other, and then FPC terminals were provided for the wiring of the touch panel. Normal operation of the touch panel was confirmed.

### COMPARATIVE EXAMPLE

A roll of PET substrate having a thickness of 50 μm was provided, a UV curable resin was applied on both surfaces of the substrate by a die coater and cured. Then, coating liquid containing dispersed silver nanowires was applied on one surface of the substrate by a die coater and cured to form the transparent conductive layer. Further, a negative dry film resist was provided by a roll laminator, exposed to light through a photomask, cured and developed. After etching by using copper (II) chloride aqueous solution, the resist was stripped using aqueous sodium hydroxide to form a diamond pattern (the pattern shaped as shown in FIG. 2). Another diamond pattern was formed on the other side of the substrate by the same procedure as described above. After that, a wiring was printed by a gravure offset printing. However, the wiring was not correctly printed due to deformation of the substrate by an effect of heat during the processes.

As described above, the effectiveness of the present invention was confirmed.

Indium tin oxide (ITO) has been predominantly used as a conductive material for touch panels. The reason is it has both high electric conductivity and high transparency as a conductive layer (conductive film), which is suitable for use as an electrode on an LCD panel. However, indium is a rare metal and may become difficult to obtain in the future. Further, it is not suitable for mass production since a vacuum process needs to be performed for film deposition. Accordingly, there is a need for developing conductive materials as an alternative to ITO. Typical examples of such materials include carbon nanotubes and silver nanowires. There are some electrodes which are uniformly coated with carbon nanotubes and silver nanowires and have conductivity and transparency higher than an ITO base material. In addition, they do not need a vacuum process for film deposition. Therefore, those materials are expected to become viable alternative conductive materials to ITO.

However, a conductive surface formed of those conductive materials may be vulnerable to high temperature and humidity compared to an ITO base material, and a loss of electric conductivity may occur when it is used alone. Accordingly, a protective layer may be formed on the conductive surface. Although the protective layer can improve durability as a conductive substrate, it may cause a problem that the patterning for the capacitance type touch panel becomes difficult and failure occurs in touch panel operation.

In addition, for a screen size of 5 inches or less such as for a smartphone, a frame which is an area that encloses the wiring needs to be small for ensuring a large operation area on the screen for a user, and a contact area between the wiring that transmits a signal from the transparent electrode and the transparent electrode needs to be of the order of 0.5 mm². As the size and weight of the touch panel decrease, the need for a thinner substrate used for touch panel increases.

However, when patterning is performed in a manufacturing process for a small-sized touch panel, the film expands and contracts in a patterning process and a winding process. As a result, misalignment in the X direction and the Y direction occurs, which leads to failure in touch panel operation. This problem is more obvious when the substrate is thinner. Depending on the winding tension and thermal history of the process, the positions of the wiring print may be significantly misaligned in the subsequent process.

The problem can be solved to some extent by providing a margin of accuracy for the post treatment processing, taking into consideration the film expansion and contraction during the patterning process. However, as the required size of touch panel decreases, the margin decreases.

Although JP-B-4888608 discloses that the wiring is disposed on the substrate and the conductive layer is formed on the wiring, there is a need to improve the reliability of the touch panel. Further, there is also a need to improve the reliability of the patterning.

The present invention has been made to solve the above problem, and an object of the invention is to provide a manufacturing method for a touch panel which prevents misalignment from occurring during wiring and provide a touch panel manufactured by the same manufacturing method.

In order to solve the above problem, an aspect of the present invention is a touch panel which includes a conductive layer which is transparent, and a wiring that transmits a signal from the conductive layer, the conductive layer and the wiring being disposed at least on one surface of the transparent substrate, wherein a protective layer for protecting the conductive layer is provided; the wiring, the conductive layer and the protective layer are formed on the transparent substrate in this order, and the conductive layer is formed by patterning after the material of the conductive layer is formed on the wiring.

Another aspect of the present invention is a touch panel which includes a conductive layer which is transparent, and a wiring that transmits a signal from the conductive layer, the conductive layer and the wiring being disposed at least on one surface of the transparent substrate, wherein a protective layer for protecting the conductive layer is provided; the conductive layer, the wiring and the protective layer are formed on the transparent substrate in this order, and the conductive layer is formed by patterning after the wiring is formed.

The protective layer may be formed by patterning, and a pattern of the conductive layer may be formed by patterning performed in a state that the conductive layer is covered by a pattern of the protective layer.

The protective layer may be formed by patterning, and a pattern of the conductive layer may be formed by patterning performed in a state that the conductive layer is covered by a pattern of the protective layer.

The transparent substrate may have a thickness of 25 μm to 250 μm.

The wiring may have a thickness of 3 μm to 10 μm.

The width of the wiring and the interval of the wiring may be 5 μm to 100 μm.

A layer having a transmittance of less than 1% for light of 365 nm wavelength may be further provided on at least one surface of the transparent substrate.

The protective layer may cover the entire conductive layer.

Another aspect of the present invention is a manufacturing method for a touch panel which includes a conductive layer which is transparent, a wiring that transmits a signal from the conductive layer, the conductive layer and the wiring being disposed at least on one surface of the transparent substrate, and a protective layer for protecting the conductive layer disposed at least on one surface, which includes etching the conductive layer after the wiring and the conductive layer are formed on the transparent substrate in this order and the protective layer is formed on the conductive layer.

Further, the manufacturing method may include etching the conductive layer after the protective layer is formed on the conductive layer in a pattern shape.

Another aspect of the present invention is a manufacturing method for a touch panel which includes a conductive layer which is transparent, a wiring that transmits a signal from the conductive layer, the conductive layer and the wiring being disposed at least on one surface of the transparent substrate, and a protective layer for protecting the conductive layer disposed at least on one surface, which includes etching the conductive layer after the conductive layer and the wiring are formed on the transparent substrate in this order and the protective layer is formed on the conductive layer.

Further, the manufacturing method may include etching the conductive layer after the protective layer is formed on the conductive layer in a pattern shape.

Another aspect of the present invention is a manufacturing method of touch panel which includes a conductive layer which is transparent, a wiring that transmits a signal from the conductive layer, the conductive layer and the wiring being disposed at least on one surface of the transparent substrate, and a protective layer for protecting the conductive layer disposed at least on one surface, which includes forming the protective layer on the conductive layer after the wiring and the conductive layer are formed on the transparent substrate in this order and the conductive layer is etched.

Another aspect of the present invention is a manufacturing method for a touch panel which includes a conductive layer which is transparent, a wiring that transmits a signal from the conductive layer, the conductive layer and the wiring being disposed at least on one surface of the transparent substrate, and a protective layer for protecting the conductive layer disposed at least on one surface, which includes forming the protective layer on the conductive layer after the conductive layer and the wiring are formed on the transparent substrate in this order and the conductive layer is etched.

In the present invention, the wiring is first formed on the substrate, and the transparent conductive layer and the protective layer are then formed in this order on the wiring, or alternatively, the wiring is formed on the transparent conductive layer which is formed on the substrate and then the protective layer is further provided thereon. Accordingly, it is possible to prevent misalignment from occurring during printing of wiring on both surfaces. Further, the conductive layer can be protected by the protective layer.

Further, since the protective layer which is formed on the conductive layer is pre-patterned, the residue between patterns can be reduced in patterning of the conductive layer.

Further, since the transparent substrate has a thickness of 25 μm to 250 μm (for example, 25 to 50 μm), the touch panel unit can be reduced in size.

Further, since the wiring has a thickness of 3 to 10 μm (for example, 3 to 6 μm), it is possible to prevent breakage in winding the film using a roll when the touch panel is manufactured by a roll to roll method. If the thickness is larger than that, a failure in resistance value of the wiring may occur.

Further, for manufacturing of an especially small-sized touch panel, it is necessary to provide thin wires and minimize the interval between the wires. Accordingly, in order to satisfy this requirement, the width of wire and the interval of wires may be 5 μm to 100 μm (for example, 15 to 20 μm).

Further, a layer that has a transmittance of less than 1% for light of 365 nm wavelength is disposed at least on one surface of the transparent substrate. Accordingly, when exposure is performed on both surfaces simultaneously particularly in patterning by photolithography, a resist can be cured without mutual interference to the exposure. Accordingly, it is possible to reduce processing steps and prevent misalignment from occurring in the patterning process of the thin film. Further, since the touch panel can be formed of a single sheet of film, it can be further reduced in size

Further, since the conductive layer is patterned before the protective layer is formed, the residue between patterns can be reduced in patterning of the conductive layer.

### INDUSTRIAL APPLICABILITY

The present invention is useful for a touch panel which has a pattern of transparent conductive layer or the like.

### REFERENCE SIGNS LIST

10 touch panel
11 transparent substrate
12 wiring
13 transparent conductive layer (conductive layer)
14 protective layer
15 UV absorbing layer
16 photomask
17 UV light source
20 shield layer
30 LCD display panel
40 front panel layer
50 adhesive layer

Obviously, numerous modifications and variations of the present invention are possible in light of the above teachings. It is therefore to be understood that within the scope of the appended claims, the invention may be practiced otherwise than as specifically described herein.

What is claimed is:

1. A touch panel, comprising:
a transparent substrate;
a wiring formed on at least one surface of the transparent substrate;
a conductive layer formed on the wiring and the transparent substrate; and
a protective layer formed on the conductive layer,
wherein the wiring is configured to transmit a signal from the conductive layer, and the conductive layer is transparent and has a pattern formed by patterning a material formed on the wiring.

2. The touch panel according to claim 1, wherein the protective layer has a pattern formed by patterning with the conductive layer being covered by the protective layer.

3. The touch panel according to claim 1, wherein the transparent substrate has a thickness in a range of from 25 μm to 250 μm.

4. The touch panel according to claim 1, wherein the wiring has a thickness in a range of from 3 μm to 10 μm.

5. The touch panel according to claim 1, wherein the wiring has a width and an interval each in a range of from 5 μm to 100 μm.

6. The touch panel according to claim 1, further comprising:
a layer which is formed on at least one surface of the transparent substrate and has a transmittance of less than 1% with respect to a light having a wavelength of 365 nm.

7. The touch panel according claim 1, wherein the protective layer covers the conductive layer entirely.

8. A touch panel, comprising:
a transparent substrate;
a conductive layer formed on at least one surface of the transparent substrate;
a wiring formed on the conductive layer and configured to transmit a signal from the conductive layer; and
a protective layer formed on the wiring and the conductive layer,
wherein the conductive layer is transparent and has a pattern formed after the wiring is formed.

9. The touch panel according to claim 8, wherein the protective layer has a pattern formed by patterning with the conductive layer being covered by the protective layer.

10. The touch panel according to claim 8, wherein the transparent substrate has a thickness in a range of from 25 μm to 250 μm.

11. The touch panel according to claim 8, wherein the wiring has a thickness in a range of from 3 μm to 10 μm.

12. The touch panel according to claim 8, wherein the wiring has a width and an interval each in a range of from 5 μm to 100 μm.

13. The touch panel according to claim 8, further comprising:
a layer which is formed on at least one surface of the transparent substrate and has a transmittance of less than 1% with respect to a light having a wavelength of 365 nm.

14. The touch panel according claim 8, wherein the protective layer covers the conductive layer entirely.

15. A method of manufacturing a touch panel, comprising:
forming a wiring on at least one surface of a transparent substrate;
forming a conductive layer on the wiring and the transparent substrate; and
forming a protective layer on the conductive layer,
wherein the conductive layer is transparent, the wiring is formed such that the wiring transmits a signal from the conductive layer, and the forming of the conductive layer includes etching the conductive layer before or after the forming of the protective layer on the conductive layer.

16. The method according to claim 15, wherein the forming of the protective layer includes patterning the protective layer, and the etching of the conductive layer is performed after the patterning of the protective layer.

17. The method according to claim 15, wherein the etching of the conductive layer is performed before the forming of the protective layer on the conductive layer.

18. A method of manufacturing a touch panel,
forming a conductive layer on at least one surface of the transparent substrate;
forming a wiring on the conductive layer such that the wiring transmits a signal from the conductive layer; and
forming a protective layer on the wiring and the conductive layer,
wherein the conductive layer is transparent, and the forming of the conductive layer includes etching the conductive layer before or after the forming of the protective layer.

19. The method according to claim 18, wherein the forming of the protective layer includes patterning the protective layer, and the etching of the conductive layer is performed after the patterning of the protective layer.

20. The method according to claim 18, wherein the etching of the conductive layer is performed before the forming of the protective layer.
